(19) United States
(12) Patent Application Publication
(10) Pub. No.: US 2026/0179933 A1
(43) Pub. Date: Jun. 25, 2026

(54) TWO-PHASE SINGLE CRYSTAL POSITIVE ELECTRODE MATERIALS FOR BATTERIES THAT CYCLE LITHIUM IONS AND METHODS OF MANUFACTURING THE SAME

(71) Applicant: GM GLOBAL TECHNOLOGY OPERATIONS LLC, Detroit, MI (US)

(72) Inventors: Vamakshi YADAV, Sterling Heights, MI (US); Lei Wang, Rockhester Hills, MI (US); Gongshin Qi, Troy, MI (US); Jun Wei Yap, Columbus, OH (US)

(21) Appl. No.: 18/989,445

(22) Filed: Dec. 20, 2024

(51) Int. Cl. H01M 4/505; C30B 29/22; H01M 4/02; H01M 4/04; H01M 4/1391; H01M 4/36; H01M 10/0525

(52) U.S. Cl. CPC H01M 4/505; C30B 29/22; H01M 4/0404; H01M 4/1391; H01M 4/366; H01M 10/0525; H01M 2004/021

(57) ABSTRACT

A method of manufacturing a positive electrode for a battery that cycles lithium ions is disclosed, as well as a battery including the positive electrode. In the disclosed method, a single crystal precursor particle is placed in contact with an aqueous solution. The precursor particle includes a lithium-rich manganese-based transition metal oxide (LRMO) having a layered crystal structure, and the aqueous solution includes exchangeable cations. When the precursor particle is placed in contact with the aqueous solution, lithium ions are removed from an exterior surface portion of the precursor particle and the LRMO in the exterior surface portion of the precursor particle is transformed into a lithium-deficient manganese-based oxide (LDMO). Then, the precursor particle is heated such that the LDMO in the exterior surface portion of the precursor particle undergoes a phase transition and is transformed into a lithium manganese-based transition metal oxide having a spinel crystal structure (spinel-LMO).

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates to positive electrodes for batteries that cycle lithium ions, and more particularly to positive electrodes comprising single crystal lithium-rich manganese-based transition metal oxides.

Layered lithium-rich manganese-based oxides (LRMO) are desirable electroactive materials for positive electrodes of batteries that cycle lithium ions due to their relatively high capacity (e.g., >250 mAh/g), thermal stability, and relatively low cost. However, during activation, LRMO may experience an irreversible phase transformation from a layered to spinel structure, which may lead to voltage fade and may degrade the long-term cycling performance of the LRMO. Using single crystal LRMO particles, instead of polycrystalline particles, has been found to help slow the undesirable phase transformation process. But single crystal LRMO particles may exhibit low initial columbic efficiency, which may limit the maximum utilization of their capacity.

### SUMMARY

A method of manufacturing a positive electrode for a battery that cycles lithium ions, in accordance with one or more embodiments of the present disclosure, comprises contacting a single crystal precursor particle with an aqueous solution. The precursor particle comprises a lithium-rich manganese-based transition metal oxide (LRMO) having a layered crystal structure. The aqueous solution comprises exchangeable cations. The precursor particle is placed in contact with the aqueous solution such that lithium ions are removed from an exterior surface portion of the precursor particle and the LRMO in the exterior surface portion of the precursor particle is transformed into a lithium-deficient manganese-based oxide (LDMO). Then, the precursor particle is heated such that the LDMO in the exterior surface portion of the precursor particle undergoes a phase transition and is transformed into a lithium manganese-based transition metal oxide having a spinel crystal structure (spinel-LMO).

In aspects, the aqueous solution may comprise an aqueous ammonium solution and the exchangeable cations comprise ammonium (NH₄⁺) ions.

In other aspects, the aqueous solution may comprise an aqueous citric acid solution and the exchangeable cations comprise hydrogen (H⁺) ions.

The amount of the exchangeable cations in the aqueous solution relative to the amount of the LRMO in the aqueous solution may be greater than or equal to 0.1 millimoles per gram of the LRMO and less than or equal to 2 millimoles per gram of the LRMO.

The precursor particle may be placed in contact with the aqueous solution at a temperature of greater than or equal to 50 degrees Celsius and less than or equal to 100 degrees Celsius for a duration of greater than or equal to 2 hours and less than or equal to 24 hours.

The precursor particle may be heated at a temperature of greater than or equal to 400 degrees Celsius and less than or equal to 700 degrees Celsius for a duration of greater than or equal to 1 hour and less than or equal to 24 hours.

The LRMO may have a composition represented by the formula Li_{y}MnₓMe₁₋ₓO₂, wherein: y is greater than 1 and less than or equal to 1.4, x is greater than 0.5 and less than 1, and Me comprises Ni, Co, or a combination thereof.

The spinel-LMO may have a composition represented by the formula Li(MnₓMe₁₋ₓ)₂O₄, wherein: x is greater than 0.5 and less than 1, and Me comprises Ni, Co, or a combination thereof.

A method of manufacturing a positive electrode for a battery that cycles lithium ions, in accordance with one or more embodiments of the present disclosure, comprises contacting a single crystal precursor particle with an aqueous ammonium solution. The precursor particle comprises a lithium-rich manganese-based transition metal oxide (LRMO) having a layered crystal structure. The aqueous ammonium solution comprises ammonium (NH₄⁺) ions. The precursor particle is placed in contact with the aqueous ammonium solution such that lithium ions are removed from an exterior surface portion of the precursor particle and the LRMO in the exterior surface portion of the precursor particle is transformed into a lithium-deficient manganese-based oxide (LDMO). Then, the precursor particle is heated such that the LDMO in the exterior surface portion of the precursor particle undergoes a phase transition and is transformed into a lithium manganese-based transition metal oxide having a spinel crystal structure (spinel-LMO), thereby forming a two-phase single crystal (2P-SC) particle. The 2P-SC particles has a core and a shell surrounding the core. The core is defined by a remaining portion of the LRMO in the precursor particle and the shell is defined by the spinel-LMO.

The aqueous ammonium solution may comprise at least one ammonium salt selected from the group consisting of ammonium persulfate, ammonium molybdate, and ammonium phosphate.

The amount of the NH₄⁺ ions in the aqueous ammonium solution relative to the amount of the LRMO in the aqueous ammonium solution may be greater than or equal to 0.1 millimoles NH₄⁺ per gram of the LRMO and less than or equal to 2 millimoles NH₄⁺ per gram of the LRMO.

The precursor particle may be placed in contact with the aqueous ammonium solution at a temperature of greater than or equal to 50 degrees Celsius and less than or equal to 100 degrees Celsius for a duration of greater than or equal to 2 hours and less than or equal to 24 hours.

The precursor particle may be heated a temperature of greater than or equal to 400 degrees Celsius and less than or equal to 700 degrees Celsius for a duration of greater than or equal to 1 hour and less than or equal to 24 hours.

The LRMO may have a composition represented by the formula Li_{y}MnₓMe₁₋ₓO₂, wherein: y is greater than 1 and less than or equal to 1.4, x is greater than 0.5 and less than 1, and Me comprises Ni, Co, or a combination thereof.

The spinel-LMO may have a composition represented by the formula Li(MnₓMe₁₋ₓ)₂O₄, wherein: x is greater than 0.5 and less than 1, and Me comprises Ni, Co, or a combination thereof.

The LRMO may have a composition represented by the formula Li_{1.2}MnₓNi₁₋ₓO₂, where x is greater than or equal to 0.6 and less than or equal to 0.9.

The 2P-SC particle may have a particle diameter of greater than or equal to 0.5 micrometers and less than or equal to 5 micrometers.

The shell may have a thickness of greater than or equal to 1 nanometer and less than or equal to 20 nanometers.

The method may further comprise: mixing the 2P-SC particle with a polymer binder, optionally an electrically conductive material, and a solvent to form a slurry; depositing the slurry on a substrate; and then removing the solvent from the slurry.

A battery that cycles lithium ions, in accordance with one or more embodiments of the present disclosure, comprises a positive electrode comprising an electroactive material comprising a two-phase single crystal (2P-SC) particle having a core and a shell surrounding the core. The core of the 2P-SC particle comprises a lithium-rich manganese-based transition metal oxide (LRMO) having a layered crystal structure. The shell of the 2P-SC particle comprises a lithium manganese-based transition metal oxide having a spinel crystal structure (spinel-LMO). The shell is formed in situ along an exterior surface portion of the 2P-SC particle by performing a cation exchange process followed by a calcination process on a single crystal precursor particle comprising the LRMO. During the cation exchange process, the precursor particle is placed in contact with an aqueous ammonium solution comprising ammonium (NH₄⁺) ions such that lithium ions are removed from an exterior surface portion of the precursor particle and the LRMO in the exterior surface portion of the precursor particle is transformed into a lithium-deficient manganese-based oxide (LDMO). Then, during the calcination process, the precursor particle is heated such that the LDMO in the exterior surface portion of the precursor particle undergoes a phase transition and is transformed into the spinel-LMO, thereby forming the 2P-SC particle, wherein the core is defined by a remaining portion of the LRMO in the precursor particle and the shell is defined by the spinel-LMO.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a schematic perspective view of an automotive vehicle powered by a battery pack that includes multiple battery modules.

FIG. 2 is a schematic cross-sectional view of a portion of one of the battery modules of FIG. 1, the battery module including multiple electrochemical cells or batteries that cycle lithium ions.

FIG. 3 is a schematic cross-sectional view of a battery that cycles lithium ions, the battery comprising a positive electrode, a negative electrode, a porous separator, and an electrolyte infiltrating the positive and negative electrodes and the porous separator.

FIG. 4 is a schematic cross-sectional view of an electroactive positive electrode material in the form of a two-phase single crystal (2P-SC) particle comprising a core and a shell surrounding the core.

FIG. 5 is a scanning electron microscope image of single crystal lithium-rich manganese-based transition metal oxide (SC-LRMO) particles.

FIGS. 6 and 7 are scanning electron microscope images of 2P-SC particles formed according to embodiments of the present disclosure.

FIG. 8 is a plot of differential capacity, dQ/dV, (mAh/V) vs. Voltage (V vs. Li/Li+) for the first cycle of: (i) a half cell comprising SC-LRMO particles as electroactive materials (solid line) and (ii) a half cell comprising 2P-SC particles as electroactive materials (dashed line).

FIG. 9 is an enlarged view of the plot of FIG. 8 taken from rectangle 9.

FIG. 10 is a plot of Coulombic Efficiency 300(%) vs. Relative Ammonium Content 400 (mmol NH₄⁺/g SC-LRMO) for the first cycle of: (i) half cells comprising 2P-SC particles formed using aqueous ammonium persulfate solutions for the ion exchange process (solid line) and (ii) half cells comprising 2P-SC particles formed using aqueous ammonium molybdate solutions for the ion exchange process (dashed line).

In the drawings, reference numbers may be reused to identify similar and/or identical elements.

### DETAILED DESCRIPTION

The presently disclosed single crystal LRMO particles have a two-phase structure and can be used as electroactive positive electrode materials in batteries that cycle lithium ions to increase the first cycle coulombic efficiency thereof, as compared to batteries that include single crystal LRMO particles without the presently disclosed two-phase structure. The presently disclosed two-phase single crystal (2P-SC) LRMO particles can be manufactured using a controlled surface reconstruction method in which single crystal LRMO particles having a layered structure are subjected to an ion exchange treatment followed by a calcination treatment to effectively transform an exterior surface portion of the LRMO particles from a layered structure to a spinel structure. The thin spinel shell on the 2P-SC LRMO particles is believed to help increase first cycle coulombic efficiency, for example, by improving the ease with which lithium ions can penetrate the surface of the particles and diffuse therein.

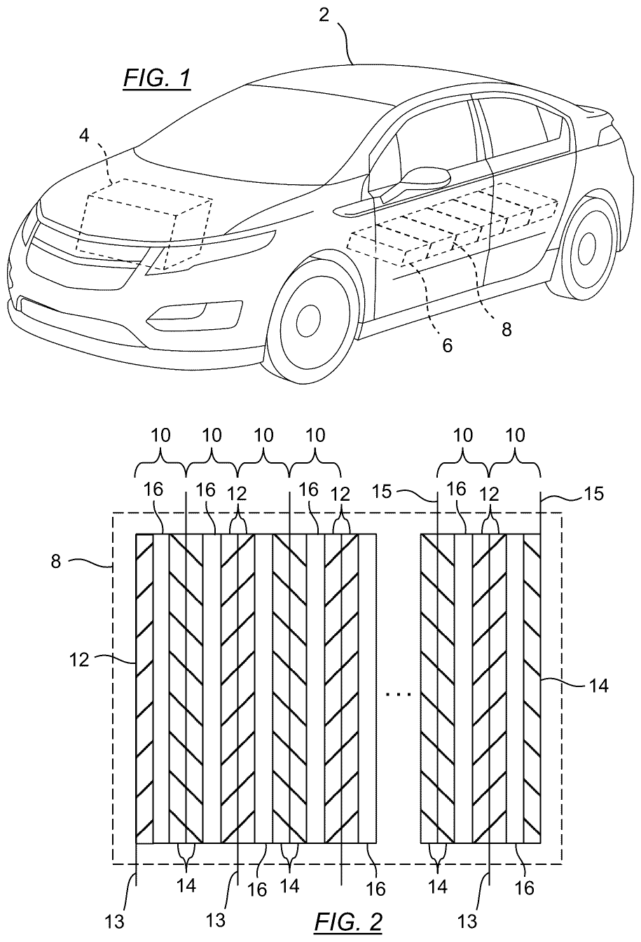

FIG. 1 depicts an automotive vehicle 2 powered by an electric motor 4 that draws electricity from a battery pack 6 including one or more battery modules 8. The battery modules 8 may be electrically coupled together in a series and/or parallel arrangement to meet desired capacity and power requirements of the electric motor 4. The vehicle 2 may be an all-electric vehicle and may be powered exclusively by the electric motor 4, or the vehicle 2 may be a hybrid electric vehicle and may be powered by the electric motor 4 and by an internal combustion engine (not shown).

As shown in FIG. 2, each battery module 8 includes one or more electrochemical cells or batteries 10 that cycle lithium ions. In practice, the batteries 10 in the battery module 8 are oftentimes assembled as a stack of layers, including negative electrode layers 12, negative electrode current collectors 13, positive electrode layers 14, positive electrode current collectors 15, and separator layers 16. Each battery 10 is defined by a negative electrode layer 12 and a positive electrode layer 14, which are spaced apart from each other by a separator layer 16. In practice, the separator layer 16 may be infiltrated with an electrolyte that provides a medium for the conduction of lithium ions between the negative electrode layer 12 and the positive electrode layer 14, or the separator layer 16 itself may function as an electrolyte. The negative electrode layers 12 are disposed on and in electrical communication with the negative electrode current collectors 13 and the positive electrode layers 14 are disposed on an in electrical communication with the positive electrode current collectors 15. As shown in FIG. 2, for efficiency, the layers may be stacked such that some of the negative electrode current collectors 13 and some of the positive electrode current collectors 15 are double sided and respectively include negative electrode layers 12 or positive electrode layers 14 on both sides thereof. In this arrangement, adjacent negative electrode layers 12 and positive electrode layers 14 respectively share a single negative electrode current collector 13 or a positive electrode current collector 15.

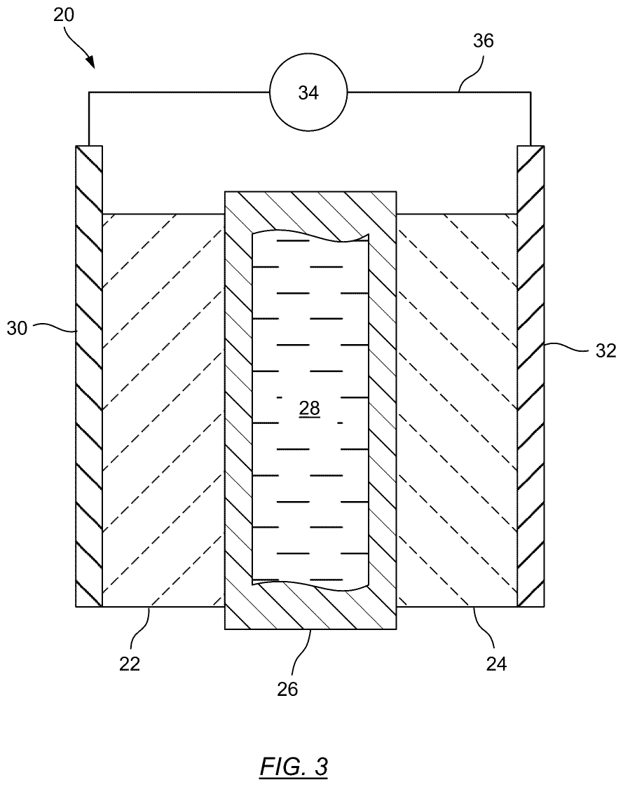

FIG. 3 depicts an electrochemical cell or battery 20 that cycles lithium ions. The battery 20 can generate an electric current during discharge, which may be used to supply power to a load device (e.g., the electric motor 4), and can be charged by being connected to a power source. Like the batteries 10 depicted in FIGS. 1 and 2, in aspects, the battery 20 may be used to supply power to an electric motor 4 of an automotive vehicle 2. Additionally or alternatively, the battery 20 may be used in other transportation applications (e.g., motorcycles, boats, tractors, buses, motorcycles, mobile homes, campers, tanks, and aircraft), and may be used to provide electricity to stationary and/or portable electronic equipment, components, and devices used in a wide variety of other industries and applications, including industrial, residential, and commercial buildings, consumer products, industrial equipment and machinery, agricultural or farm equipment, and heavy machinery, by way of nonlimiting example.

The battery 20 comprises a negative electrode 22, a positive electrode 24, a separator 26, and an electrolyte 28 that provides a medium for conduction of lithium ions between the negative electrode 22 and the positive electrode 24. The negative electrode 22 is disposed on a major surface of a negative electrode current collector 30 and the positive electrode 24 is disposed on a major surface of a positive electrode current collector 32. In practice, the negative electrode current collector 30 and the positive electrode current collector 32 are electrically coupled to a power source or load 34 (e.g., the electric motor 4) via an external circuit 36. The negative electrode 22 and the positive electrode 24 are formulated such that, when the battery 20 is at least partially charged, an electrochemical potential difference is established between the negative electrode 22 and the positive electrode 24. During discharge of the battery 20, the electrochemical potential established between the negative electrode 22 and the positive electrode 24 drives spontaneous reduction and oxidation (redox) reactions within the battery 20 and the release of lithium ions and electrons from the negative electrode 22. The released lithium ions travel from the negative electrode 22 to the positive electrode 24 through the separator 26 and the electrolyte 28, while the electrons travel from the negative electrode 22 to the positive electrode 24 via the external circuit 36, which generates an electric current. After the negative electrode 22 has been partially or fully depleted of lithium, the battery 20 may be charged by connecting the negative electrode 22 and the positive electrode 24 to the power source 34, which drives nonspontaneous redox reactions within the battery 20 and the release of the lithium ions and the electrons from the positive electrode 24. The repeated discharge and charge of the battery 20 may be referred to herein as “cycling,” with a full charge event followed by a full discharge event being considered a full cycle.

The positive electrode 24 comprises an electroactive material (electroactive positive electrode material) that can store and release lithium ions by undergoing a reversible redox reaction with lithium at a higher electrochemical potential than the electrochemically active material of the negative electrode 22 such that an electrochemical potential difference exists between the negative electrode 22 and the positive electrode 24. The electroactive material of the positive electrode 24 is a particulate material and particles of the electroactive positive electrode material may be intermingled with a polymer binder and optionally an electrically conductive material in the positive electrode 24. The positive electrode 24 may be in the form of a continuous porous layer disposed on the major surface of the positive electrode current collector 32.

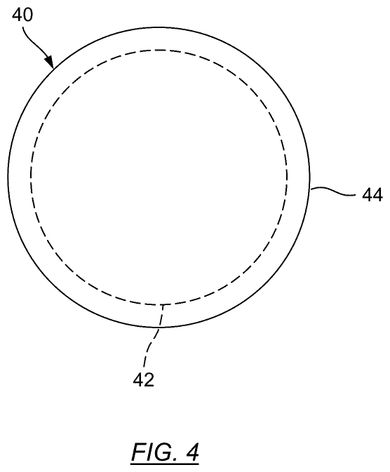

Referring now to FIG. 4, at least one of the electroactive material particles of the positive electrode 24 is a two-phase single crystal (2P-SC) particle 40 having a core 42 and a shell 44 surrounding the core 42. The 2P-SC particle 40 comprises a lithium- and manganese-containing oxide; however, the composition and crystal structure of the core 42 are different from that of the shell 44. The 2P-SC particle 40 may have a particle diameter of greater than or equal to 0.5 micrometers and less than or equal to 5 micrometers. The at least one 2P-SC particle 40 may constitute, by weight, greater than or equal to 80%, optionally greater than or equal to 90%, or optionally greater than or equal to 95% and less than or equal to 99% of the positive electrode 24.

The core 42 of the 2P-SC particle 40 comprises a lithium-rich manganese-based transition metal oxide (LRMO) having a layered crystal structure. The LRMO of the core 42 has a composition represented by the formula Li_{y}MnₓMe₁₋ₓO₂, where y is greater than 1, optionally greater than or equal to 1.1, optionally greater than or equal to 1.2, and less than or equal to 1.4, or optionally less than or equal to 1.33, x is greater than 0.5, optionally greater than or equal to 0.6, or optionally greater than or equal to 0.7, and less than 1, optionally less than or equal to 0.9, or optionally less than or equal to 0.8, and Me is a transition metal (e.g., Co, Ni, Fe, Al, V, or a combination thereof). In aspects, Me may comprise Ni and/or Co. For example, in aspects, the LRMO of the core 42 may comprise a lithium nickel manganese oxide (LNMO) represented by the formula Li_{1.2}MnₓNi₁₋ₓO₂, where x is greater than 0.5, or optionally greater than or equal to 0.6, and less than 1, or optionally less than or equal to 0.9.

The shell 44 of the 2P-SC particle 40 comprises a lithium manganese-based transition metal oxide having a spinel crystal structure (spinel-LMO). The spinel-LMO of the shell 44 may have a composition represented by the formula Li(MnₓMe₁₋ₓ) 204, where x is greater than 0.5, optionally greater than or equal to 0.6, or optionally greater than or equal to 0.7, and less than 1, optionally less than or equal to 0.9, or optionally less than or equal to 0.8, and Me is a transition metal. In aspects, Me may comprise Ni and/or Co. For example, in aspects, the spinel-LMO of the shell 44 may comprise a lithium nickel manganese oxide. The shell 44 of the 2P-SC particle 40 may have a thickness of greater than or equal to 1 nanometer and less than or equal to 20 nanometers. The shell 44 of the 2P-SC particle 40 is formed in situ using a controlled surface reconstruction method, and not by depositing material on the core 42. As such, like the core 42, the shell 44 does not comprise an agglomerate of particles.

In addition to the 2P-SC particle 40, the electroactive material of the positive electrode 24 may further comprise a layered lithium transition metal oxide represented by the formula LiMeO₂ and/or Li₂MeO₃, a layered lithium-rich transition metal oxide represented by the formula Li₁₊ₓMe₁₋ₓO₂ (where 0<x≤0.33), an olivine-type lithium transition metal oxide represented by the formula LiMePO₄, a monoclinic-type lithium transition metal oxide represented by the formula Li₃Me₂(PO₄)₃, a spinel-type lithium transition metal oxide represented by the formula LiMe₂O₄, a tavorite represented by one or both of the following formulas LiMeSO₄F or LiMePO₄F, or a combination thereof, where Me is a transition metal (e.g., Co, Ni, Mn, Fe, Al, V, or a combination thereof). The electroactive material of the positive electrode 24 may constitute, may constitute, by weight, greater than or equal to 80%, optionally greater than or equal to 90%, or optionally greater than or equal to 95% and less than or equal to 99% of the positive electrode 24.

The polymer binder is electrochemically inactive and may be included in the positive electrode 24 to provide the positive electrode 24 with structural integrity and/or to help the positive electrode 24 adhere to the major surface of the positive electrode current collector 32. Examples of polymer binders include polyvinylidene fluoride (PVdF), polytetrafluoroethylene (PTFE), ethylene propylene diene monomer (EPDM) rubber, styrene butadiene rubber (SBR), carboxymethyl cellulose (CMC), nitrile butadiene rubber (NBR), styrene-butadiene rubber (SBR), styrene ethylene butylene styrene copolymer (SEBS), polyacrylates, alginates, polyacrylic acid, and combinations thereof. The polymer binder may constitute, by weight, greater than or equal to 1%, or optionally greater than or equal to 5%, and less than or equal to 10% of the positive electrode 24.

The optional electrically conductive material is electrochemically inactive and may be included in the positive electrode 24 to provide the positive electrode 24 with electrical conductivity. Examples of electrically conductive materials include carbon-based materials, metals (e.g., nickel), and/or electrically conductive polymers. Examples of electrically conductive carbon-based materials include carbon black (CB) (e.g., acetylene black), graphite, graphene (e.g., graphene nanoplatelets, GNP), graphene oxide, carbon nanotubes (CNT), and/or carbon fibers (e.g., carbon nanofibers). Examples of electrically conductive polymers include polyaniline, polythiophene, polyacetylene, and/or polypyrrole. When included in the positive electrode 24, the optional electrically conductive material may constitute, by weight, greater than 0%, optionally greater than or equal to 1%, or optionally greater than or equal to 5% and less than or equal to 10% of the positive electrode 24.

The negative electrode 22 comprises an electroactive material that is formulated to directly participate in the electrochemical reactions that store and release energy from the battery 20 and may be in the form of a continuous porous or nonporous layer of material disposed on a major surface of the negative electrode current collector 30. The electroactive material of the negative electrode 22 (electroactive negative electrode material) may be lithium and/or may be a material that is formulated to store and release lithium ions by undergoing a reversible redox reaction with lithium during charge and discharge of the battery 20. Examples of electroactive negative electrode materials that can store and release lithium include carbon-based materials (e.g., graphite), silicon, silicon-based materials (e.g., alloys of silicon and lithium), silicon oxide (SiOₓ), silicon oxide-based materials (e.g., lithium silicon oxide, LiSiOₓ), lithium oxide-based materials (e.g., lithium titanate), and combinations thereof. Like the electroactive positive electrode material, the electroactive negative electrode material may be a particulate material and particles of the electroactive material of the negative electrode 22 may be intermingled with a polymer binder and optionally an electrically conductive material.

The separator 26 physically separates and electrically isolates the negative electrode 22 and the positive electrode 24 from each other while permitting lithium ions to pass therethrough. The separator 26 has an open microporous structure and may comprise an organic and/or inorganic material. For example, the separator 26 may comprise a polymer.

The electrolyte 28 is ionically conductive and provides a medium for the conduction of lithium ions between the negative electrode 22 and the positive electrode 24. The electrolyte 28 may comprise a nonaqueous aprotic organic solvent and a lithium salt (e.g., LiPF₆) in the organic solvent. Non-limiting examples of nonaqueous aprotic organic solvents include cyclic carbonates (e.g., ethylene carbonate (EC), propylene carbonate (PC), fluoroethylene carbonate (FEC), and vinylene carbonate (VC)); linear carbonates (e.g., dimethyl carbonate (DMC), diethyl carbonate (DEC), ethyl methyl carbonate (EMC)); and combinations thereof.

The negative electrode current collector 30 and the positive electrode current collector 32 are electrically conductive, electrochemically inactive, and provide an electrical connection between the external circuit 36 and the negative electrode 22 and the positive electrode 24, respectively. The negative electrode current collector 30 and the positive electrode current collector 32 each individually may be made of metal or another appropriate electrically conductive material.

### Methods

The 2P-SC particle 40 may be manufactured by performing a cation exchange process followed by a calcination process on a single crystal precursor particle. The following description relates to the manufacture of a single 2P-SC particle 40 from one individual single crystal precursor particle. However, the methods described herein may be used to simultaneously manufacture a plurality of 2P-SC particles from a plurality of single crystal precursor particles, as would be recognized by one of ordinary skill in the art.

The precursor particle may have substantially the same composition and crystal structure as that of the core 42 of the 2P-SC particle 40. For example, the precursor particle may have a layered crystal structure and may comprise a lithium-rich manganese-based transition metal oxide (LRMO). The precursor particle may have substantially the same size as that of the 2P-SC particle 40. For example, the precursor particle may have a particle diameter of greater than or equal to 0.5 micrometers and less than or equal to 5 micrometers. In embodiments where the presently disclosed methods are used to manufacture a plurality of 2P-SC particles, the plurality of single crystal precursor particles may have a mean particle diameter of greater than or equal to 0.5 micrometers and less than or equal to 5 micrometers.

The LRMO is referred to as “lithium-rich” because it comprises a greater than stoichiometric amount of lithium, as compared to the amount of lithium that would be necessary to satisfy the formula LiMeO₂. The layered crystal structure of the LRMO comprises a repeating transition metal (TM) layer, oxygen (O) layer, and lithium (Li) layer. The TM layer comprises transition metal (Me) ions (e.g., Mn ions and Ni ions) and the O layer comprises oxygen anions (O²⁻). Because the LRMO comprises a stoichiometric excess of Li, the TM layer also comprises Li+ ions.

A cation exchange process is performed on the precursor particle by contacting the precursor particle with an aqueous solution comprising a plurality of exchangeable cations such that a portion of the lithium ions in the LRMO in an exterior surface portion of the precursor particle are removed therefrom and replaced with the exchangeable cations. The removal of lithium ions from the LRMO in the exterior surface portion of the precursor particle changes the chemical composition of the material in the exterior surface portion of the precursor particle. Specifically, the removal of lithium ions from the LRMO transforms the LRMO in the exterior surface portion of the precursor particle to a lithium-deficient manganese-based oxide (LDMO). The LDMO is referred to as “lithium-deficient” because it comprises a less than stoichiometric amount of lithium, as compared to the amount of lithium that would be necessary to satisfy the formula LiMeO₂.

In embodiments, the aqueous solution used to perform the cation exchange process may comprise an aqueous ammonium solution and the exchangeable cations may comprise ammonium ions (NH₄⁺). The aqueous ammonium solution may comprise at least one ammonium salt selected from the group consisting of ammonium persulfate, ammonium molybdate, and ammonium phosphate. In other embodiments, the aqueous solution used to perform the cation exchange process may comprise an aqueous citric acid solution and the exchangeable cations may comprise hydrogen (H⁺) ions.

The aqueous solution is formulated to promote an exchange between the cations dissolved in the aqueous solution and the Lit ions in the LRMO and to prevent or inhibit dissolution and/or removal of transition metals from the LRMO during the cation exchange process. Preventing or inhibiting the dissolution and/or removal of transition metals from the LRMO during the cation exchange process may help ensure that the 2P-SC particle 40 has a single crystal structure and consists essentially or consists of two phases, the layered LRMO in the core 42 and the spinel-LMO in the shell 44.

For example, the ammonium salts included in the aqueous ammonium solution are preferably selected so that, during the cation exchange process, Lit ions are effectively removed from the crystal structure of the LRMO in the exterior surface portion of the precursor particle, without removing transition metals (e.g., Mn and/or Ni) therefrom. In addition, the ammonium salts included in the aqueous ammonium solution are preferably selected so that, during the cation exchange process, Li+ ions are only extracted from the exterior surface portion of the precursor particle, and not from a remaining bulk portion of the precursor particle.

The amount of the exchangeable cations in the aqueous solution may be selected based on the amount of the precursor particle in the aqueous solution and may be modified and/or adjusted based on the exchange rate of the cations in the aqueous solution. In addition, the amount of the exchangeable cations in the aqueous solution may be selected to achieve a desired balance between the amount the first cycle coulombic efficiency of the battery 20 is increased due to formation of the spinel-LMO and the amount the cycle life of the battery 20 is decreased due to the removal of active lithium from the LRMO. In aspects, the amount of the exchangeable cations in the aqueous solution relative to the amount of the precursor particle in the aqueous solution may be greater than or equal to 0.1 millimoles (mmol), optionally greater than or equal to 0.5 mmol, or optionally greater than or equal to 0.8 mmol, and less than or equal to 2 mmol, optionally less than or equal to 1.5 mmol, or optionally less than or equal to 1.2 mmol per gram of the precursor particle in the aqueous solution. For example, in aspects where the aqueous solution comprises an aqueous ammonium solution, the moles of NH₄⁺ ions in the aqueous solution relative to the grams of the precursor particle in the aqueous solution may be greater than or equal to 0.1 mmol, optionally greater than or equal to 0.5 mmol, or optionally greater than or equal to 0.8 mmol, and less than or equal to 2 mmol, optionally less than or equal to 1.5 mmol, or optionally less than or equal to 1.2 mmol per gram of the precursor particle in the aqueous solution.

In aspects, the concentration of the precursor particle in the aqueous solution may be, by weight, greater than or equal to 0.1%, optionally greater than or equal to 0.5%, or optionally greater than or equal to 1%, and less than or equal to 50%, optionally less than or equal to 10%, or optionally less than or equal to 5%, based on the total weight of the aqueous solution. This may mean that the concentration of the exchangeable cations in the aqueous solution may be greater than or equal to 0.5 millimolar (mM), optionally greater than or equal to 1 mM, optionally greater than or equal to 2 mM, or optionally greater than or equal to 5 mM, and less than or equal to 20 mM, optionally less than or equal to 15 mM, or optionally less than or equal to 10 mM.

During the cation exchange process, the precursor particle may be placed in contact with the aqueous solution comprising the exchangeable cations at a temperature of greater than or equal to 50 degrees Celsius (C) and less than or equal to 100° C. for a duration of greater than or equal to 2 hours and less than or equal to 24 hours. In aspects, the cation exchange process may be performed at a temperature of about 80° C. for about 15 hours.

In aspects, the cation exchange process may be performed as a batch process and the precursor particle and the aqueous solution may be mixed, for example, in a stirred tank reactor during the cation exchange process. Additionally or alternatively, the cation exchange process may be performed as a continuous process and the precursor particle may be in contact with a stream of the aqueous solution, for example, in a packed bed reactor.

After completion of the cation exchange process, the precursor particle may be separated from the aqueous solution, e.g., by filtration, and washed with water or with an additional amount of the aqueous solution.

After the precursor particle has been separated from the aqueous solution, the precursor particle is subjected to a calcination process to form the 2P-SC particle 40. During the calcination process, the precursor particle is heated such that the LDMO in the exterior surface portion of the precursor particle undergoes a phase transition and is transformed into a lithium manganese-based transition metal oxide having a spinel crystal structure (spinel-LMO), thereby forming the 2P-SC particle 40. In the 2P-SC particle 40, the core 42 is defined by a remaining portion of the LDMO and the shell 44 is defined by the spinel-LMO. The phase transition that occurs in the exterior surface portion of the precursor particle during the calcination process is induced by the lithium deficiencies in the LDMO. During the calcination process, the precursor particle may be heated in air at a temperature of greater than or equal to 400° C. and less than or equal to 700° C. for a duration of 1 hour to 24 hours.

Although the calcination process transitions the structure of the oxide material in the exterior surface portion of the precursor particle from a layered structure to a spinel structure, the calcination process does not change the precursor particle into a polycrystalline material. As such, the resulting 2P-SC particle 40 is a single crystal particle having two phases, with a layered phase in its core 42 and a spinel phase in its shell 44.

After completion of the calcination process, the 2P-SC particles 40 may be used as electroactive positive electrode materials in batteries that cycle lithium ions, such as the battery 20. Positive electrodes may be prepared comprising the 2P-SC particles 40 by mixing the 2P-SC particles 40 with a polymer binder, optionally an electrically conductive material, and a solvent to form a slurry, depositing the slurry on a substrate, and then removing the solvent therefrom.

### Experimental

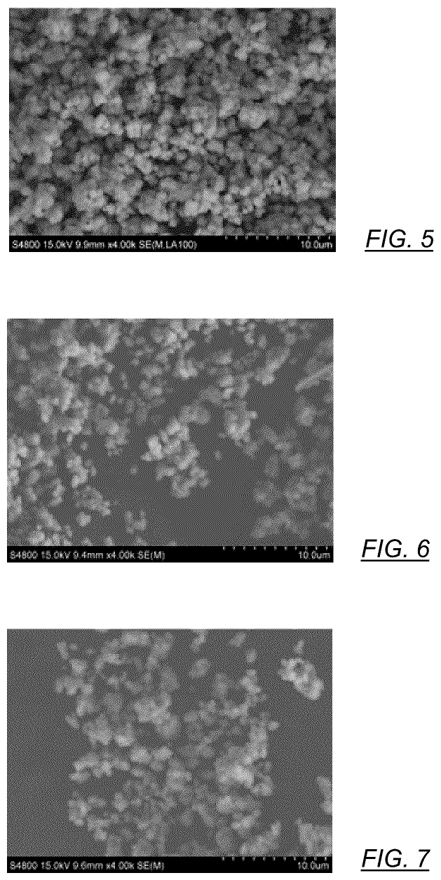

Example 2P-SC particles were prepared using single crystal lithium-rich manganese-based transition metal oxide (SC-LRMO) particles having a layered crystal structure and a composition represented by the formula Li_{1.2}MnₓNi₁₋ₓO₂, where x=0.7. FIG. 5 is a scanning electron microscope image of a plurality of the SC-LRMO particles taken prior to performing the following experiments.

Six different aqueous ammonium solutions were prepared by dissolving ammonium persulfate ((NH₄)₂S₂O₈, MW=228.2 g/mol) (APS) or ammonium molybdate ((NH₄)₂MoO₄, MW=1163.9 g/mol) (AMB) in water. The concentration of ammonium ions (NH₄⁺) in each of the as-prepared aqueous ammonium solutions is shown in Table 1 below.

TABLE 1

| | | | | mmoles |
|---|---|---|---|---|
| | water | APS | AMB | NH₄⁺ per |
| Soln. # | (mL) | (g) | (g) | liter (mM) |
| 1 | 300 | 0.06 | — | 1.75 |
| 2 | 300 | 0.3 | — | 8.76 |
| 3 | 300 | 0.6 | — | 17.53 |
| 4 | 300 | — | 0.06 | 1.03 |
| 5 | 300 | — | 0.3 | 5.16 |
| 6 | 300 | — | 0.6 | 10.31 |

3 grams of the SC-LRMO particles were added to each of the as-prepared aqueous ammonium solutions to form NH₄⁺/SC-LRMO mixtures. Details regarding the formulations of the NH₄⁺/SC-LRMO mixtures are shown in Table 2 below.

TABLE 2

| | | | | | g APS/ | g AMB/ | mmol |
|---|---|---|---|---|---|---|---|
| | | SC- | | | g SC- | g SC- | NH₄⁺/ |
| Mix | water | LRMO | APS | AMB | LRMO | LRMO | g SC- |
| # | (mL) | (g) | (g) | (g) | (%) | (%) | LRMO |
| 1 | 300 | 3 | 0.06 | — | 2 | — | 0.18 |
| 2 | 300 | 3 | 0.3 | — | 10 | — | 0.88 |
| 3 | 300 | 3 | 0.6 | — | 20 | — | 1.75 |
| 4 | 300 | 3 | — | 0.06 | — | 2 | 0.10 |
| 5 | 300 | 3 | — | 0.3 | — | 10 | 0.52 |
| 6 | 300 | 3 | — | 0.6 | — | 20 | 1.03 |

The NH₄⁺/SC-LRMO mixtures were stirred in a stirred tank reactor at a temperature of about 80° C. for a duration of about 15 hours to affect an ion exchange between the lithium ions in an exterior surface portion of the SC-LRMO particles and the NH₄⁺ ions in the ammonium solutions. After completion of the ion exchange process, the SC-LRMO particles were separated from their respective ammonium solutions by filtration and washed with water to remove byproducts of the ion exchange process therefrom. The ion-exchanged SC-LRMO particles were calcined in air at a temperature of about 450° C. for about 2 hours to form 2P-SC particles.

FIG. 6 is a scanning electron microscope image of 2P-SC particles formed using NH₄⁺/SC-LRMO mixture #6(1.03 mmol NH₄⁺/g SC-LRMO) for the ion exchange process. FIG. 7 is a scanning electron microscope image of 2P-SC particles formed using NH₄⁺/SC-LRMO mixture #3(1.75 mmol NH₄⁺/g SC-LRMO) for the ion exchange process. As shown, the ion exchange and calcination processes did not visibly impact or change the surface morphology of 2P-SC particles, as compared to that of the SC-LRMO particles, indicating that the layered to spinel transformation only occurs in a few surface layers of the particles.

Positive electrodes were prepared using the as-formed 2P-SC particles as electroactive materials. Positive electrodes were prepared using 2P-SC particles formed using NH₄⁺/SC-LRMO mixtures #1, #2, #3, #4, and #5 for the ion exchange process. For comparison, positive electrodes were also prepared using SC-LRMO particles as electroactive materials. The positive electrodes were prepared by mixing the SC-LRMO particles or the 2P-SC particles with a polymer binder, an electrically conductive material, and a solvent to form a slurry, depositing the slurry on a substrate, and then removing the solvent therefrom. The as-formed positive electrodes were assembled into half cells and evaluated using cyclic voltammetry. The half cells included an electrolyte consisting of 1.2 Molar LiPF₆ in a mixture of FEC and DEC (FEC:DEC=1:4 vol/vol) with 1 wt. % bis(trimethylsilyl)phosphite) and lithium metal as a counter electrode.

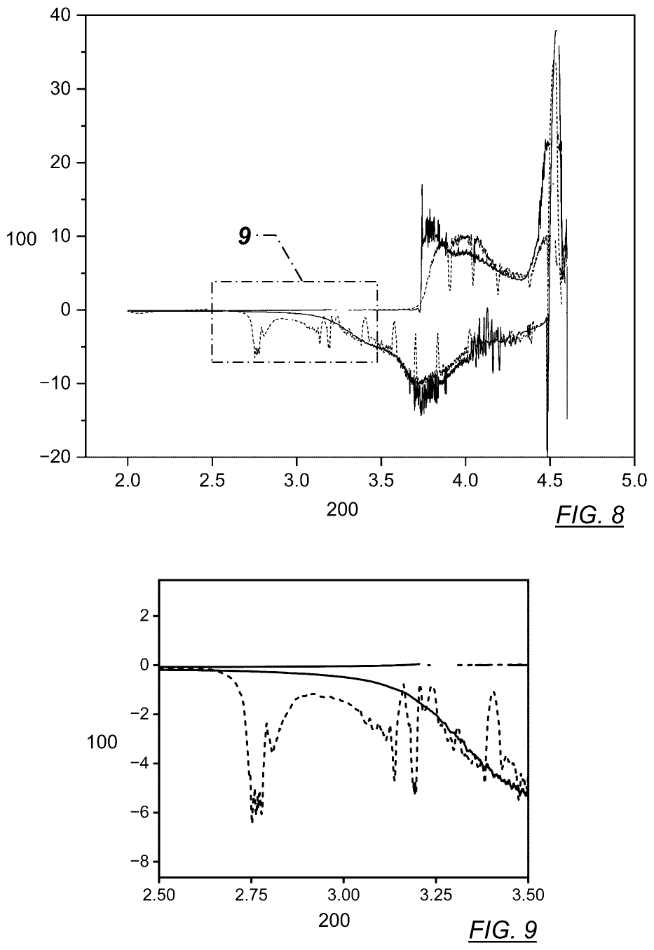

During the initial formation cycle, the cells were charged at a C/20 rate to 4.6 V and then discharged at a C/20 rate to 2.0 V. FIG. 8 is a plot of differential capacity, dQ/dV, (mAh/V) 100 vs. Voltage (V vs. Li/Li+) 200 for the first formation cycle of: (i) a cell comprising the SC-LRMO particles as electroactive materials (solid line) and (ii) a cell comprising 2P-SC particles formed using NH₄⁺/SC-LRMO mixture #5 for the ion exchange process (dashed line). As best shown in FIG. 9, the local minimum at about 2.75 Volts in the dQ/dV curve for the cell comprising the 2P-SC particles (dashed line) is evidence of formation of the spinel-LMO phase in the shells of the 2P-SC particles.

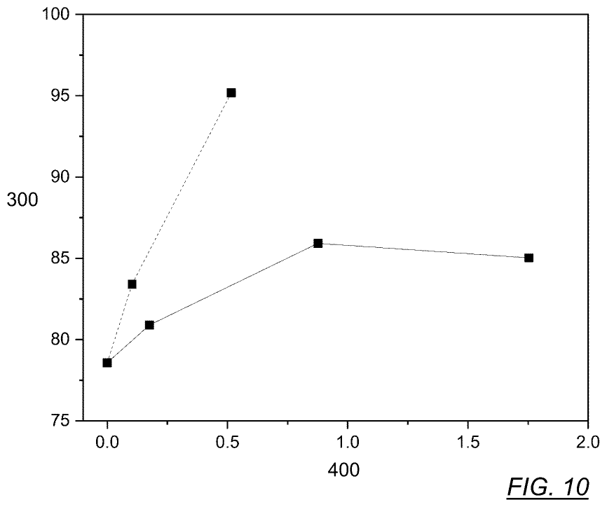

FIG. 10 is a plot of Coulombic Efficiency 300(%) vs. Relative Ammonium Content 400 (mmol NH₄⁺/g SC-LRMO) for the first formation cycle of: (i) cells comprising 2P-SC particles formed using NH₄⁺/SC-LRMO mixtures #1, #2, and #3 for the ion exchange process (solid line) and (ii) cells comprising 2P-SC particles formed using NH₄⁺/SC-LRMO mixtures #4 and #5 for the ion exchange process (dashed line).

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

The terminology used herein is for the purpose of describing example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, elements, compositions, steps, integers, operations, and/or components, but do not preclude the presence or addition of one or more other features, integers, steps, operations, elements, components, and/or groups thereof. Although the open-ended terms “comprises,” “comprising,” “including,” and “having,” are to be understood as non-restrictive terms used to describe and claim various embodiments set forth herein, in certain aspects, the terms may alternatively be understood to instead be a more limiting and restrictive term, such as “consisting of” or “consisting essentially of.” Thus, for any given embodiment reciting compositions, materials, components, elements, ingredients, features, integers, operations, and/or process steps, the present disclosure also specifically includes embodiments consisting of, or consisting essentially of, such recited compositions, materials, components, elements, ingredients, features, integers, operations, and/or process steps. In the case of “consisting of,” the alternative embodiment excludes any additional compositions, materials, components, elements, ingredients, features, integers, operations, and/or process steps, while in the case of “consisting essentially of,” any additional compositions, materials, components, elements, ingredients, features, integers, operations, and/or process steps that materially affect the basic and novel characteristics are excluded from such an embodiment, but any compositions, materials, components, elements, ingredients, features, integers, operations, and/or process steps that do not materially affect the basic and novel characteristics can be included in the embodiment.

As used herein, the phrase at least one of A, B, and C should be construed to mean a logical (A OR B OR C), using a non-exclusive logical OR, and should not be construed to mean “at least one of A, at least one of B, and at least one of C.”

As used herein, the terms “composition” and “material” are used interchangeably to refer broadly to a substance containing at least the preferred chemical constituents, elements, or compounds, but which may also comprise additional elements, compounds, or substances, including trace amounts of impurities, unless otherwise indicated. An “X-based” composition or material broadly refers to compositions or materials in which “X” is the single largest constituent of the composition or material on a weight percentage (%) basis. This may include compositions or materials having, by weight, greater than 50% X, as well as those having, by weight, less than 50% X, so long as X is the single largest constituent of the composition or material based upon its overall weight. When a composition or material is referred to as being “substantially free” of a substance, the composition or material may comprise, by weight, less than 5%, optionally less than 3%, optionally less than 1%, or optionally less than 0.1% of the substance.

What is claimed is:

1. A method of manufacturing a positive electrode for a battery that cycles lithium ions, the method comprising:
contacting a single crystal precursor particle comprising a lithium-rich manganese-based transition metal oxide (LRMO) having a layered crystal structure with an aqueous solution comprising exchangeable cations such that lithium ions are removed from an exterior surface portion of the precursor particle and the LRMO in the exterior surface portion of the precursor particle is transformed into a lithium-deficient manganese-based oxide (LDMO); and
heating the precursor particle such that the LDMO in the exterior surface portion of the precursor particle undergoes a phase transition and is transformed into a lithium manganese-based transition metal oxide having a spinel crystal structure (spinel-LMO).

2. The method of claim 1, wherein the aqueous solution comprises an aqueous ammonium solution and the exchangeable cations comprise ammonium (NH₄⁺) ions.

3. The method of claim 1, wherein the aqueous solution comprises an aqueous citric acid solution and the exchangeable cations comprise hydrogen (H⁺) ions.

4. The method of claim 1, wherein the amount of the exchangeable cations in the aqueous solution relative to the amount of the LRMO in the aqueous solution is greater than or equal to 0.1 millimoles per gram of the LRMO and less than or equal to 2 millimoles per gram of the LRMO.

5. The method of claim 1, wherein contact between the precursor particle and the aqueous solution is performed at a temperature of greater than or equal to 50 degrees Celsius and less than or equal to 100 degrees Celsius for a duration of greater than or equal to 2 hours and less than or equal to 24 hours.

6. The method of claim 1, wherein the precursor particle is heated at a temperature of greater than or equal to 400 degrees Celsius and less than or equal to 700 degrees Celsius for a duration of greater than or equal to 1 hour and less than or equal to 24 hours.

7. The method of claim 1, wherein the LRMO has a composition represented by the formula Li_{y}MnₓMe₁₋ₓO₂, wherein:
y is greater than 1 and less than or equal to 1.4,
x is greater than 0.5 and less than 1, and
Me comprises Ni, Co, or a combination thereof.

8. The method of claim 7, wherein the spinel-LMO has a composition represented by the formula Li(MnₓMe₁₋ₓ)₂O₄, wherein:
x is greater than 0.5 and less than 1, and
Me comprises Ni, Co, or a combination thereof.

9. A method of manufacturing a positive electrode for a battery that cycles lithium ions, the method comprising:
contacting a single crystal precursor particle comprising a lithium-rich manganese-based transition metal oxide (LRMO) having a layered crystal structure with an aqueous ammonium solution comprising ammonium (NH₄⁺) ions such that lithium ions are removed from an exterior surface portion of the precursor particle and the LRMO in the exterior surface portion of the precursor particle is transformed into a lithium-deficient manganese-based oxide (LDMO); and
heating the precursor particle such that the LDMO in the exterior surface portion of the precursor particle undergoes a phase transition and is transformed into a lithium manganese-based transition metal oxide having a spinel crystal structure (spinel-LMO), thereby forming a two-phase single crystal (2P-SC) particle having a core and a shell surrounding the core, wherein the core is defined by a remaining portion of the LRMO in the precursor particle and the shell is defined by the spinel-LMO.

10. The method of claim 9, wherein the aqueous ammonium solution comprises at least one ammonium salt selected from the group consisting of ammonium persulfate, ammonium molybdate, and ammonium phosphate.

11. The method of claim 9, wherein the amount of the NH₄⁺ ions in the aqueous ammonium solution relative to the amount of the LRMO in the aqueous ammonium solution is greater than or equal to 0.1 millimoles NH₄⁺ per gram of the LRMO and less than or equal to 2 millimoles NH₄⁺ per gram of the LRMO.

12. The method of claim 9, wherein contact between the precursor particle and the aqueous ammonium solution is performed at a temperature of greater than or equal to 50 degrees Celsius and less than or equal to 100 degrees Celsius for a duration of greater than or equal to 2 hours and less than or equal to 24 hours.

13. The method of claim 9, wherein the precursor particle is heated a temperature of greater than or equal to 400 degrees Celsius and less than or equal to 700 degrees Celsius for a duration of greater than or equal to 1 hour and less than or equal to 24 hours.

14. The method of claim 9, wherein the LRMO has a composition represented by the formula Li_{y}MnₓMe₁₋ₓO₂, wherein:
y is greater than 1 and less than or equal to 1.4,
x is greater than 0.5 and less than 1, and
Me comprises Ni, Co, or a combination thereof.

15. The method of claim 14, wherein the spinel-LMO has a composition represented by the formula Li(MnₓMe₁₋ₓ)₂O₄, wherein:
x is greater than 0.5 and less than 1, and
Me comprises Ni, Co, or a combination thereof.

16. The method of claim 9, wherein the LRMO has a composition represented by the formula Li_{1.2}MnₓNi₁₋ₓO₂, where x is greater than or equal to 0.6 and less than or equal to 0.9.

17. The method of claim 9, wherein the 2P-SC particle has a particle diameter of greater than or equal to 0.5 micrometers and less than or equal to 5 micrometers.

18. The method of claim 17, wherein the shell has a thickness of greater than or equal to 1 nanometer and less than or equal to 20 nanometers.

19. The method of claim 9, further comprising:
mixing the 2P-SC particle with a polymer binder, optionally an electrically conductive material, and a solvent to form a slurry;
depositing the slurry on a substrate; and
removing the solvent from the slurry.

20. A battery that cycles lithium ions, the battery comprising:
a positive electrode comprising an electroactive material comprising a two-phase single crystal (2P-SC) particle having a core and a shell surrounding the core, the core comprising a lithium-rich manganese-based transition metal oxide (LRMO) having a layered crystal structure and the shell comprising a lithium manganese-based transition metal oxide having a spinel crystal structure (spinel-LMO), the shell being formed in situ along an exterior surface portion of the 2P-SC particle by:
contacting a single crystal precursor particle comprising the LRMO and having a layered crystal structure with an aqueous ammonium solution comprising ammonium (NH₄⁺) ions such that lithium ions are removed from an exterior surface portion of the precursor particle and the LRMO in the exterior surface portion of the precursor particle is transformed into a lithium-deficient manganese-based oxide (LDMO), and then
heating the precursor particle such that the LDMO in the exterior surface portion of the precursor particle undergoes a phase transition and is transformed into the spinel-LMO, thereby forming the 2P-SC particle, wherein the core is defined by a remaining portion of the LRMO in the precursor particle and the shell is defined by the spinel-LMO.
